(19) United States
(12) Patent Application Publication
(10) Pub. No.: US 2013/0020581 A1
(43) Pub. Date: Jan. 24, 2013

(54) EPITAXIAL WAFER INCLUDING NITRIDE-BASED SEMICONDUCTOR LAYERS

(71) Applicants: Nobuaki TERAGUCHI, Osaka-shi (JP); Daisuke Honda, Osaka-shi (JP); Nobuyuki Ito, Osaka-shi (JP); Motoji Yagura, Osaka-shi (JP)

(72) Inventors: Nobuaki TERAGUCHI, Osaka-shi (JP); Daisuke Honda, Osaka-shi (JP); Nobuyuki Ito, Osaka-shi (JP); Motoji Yagura, Osaka-shi (JP)

(73) Assignee: Sharp Kabushiki Kaisha, Osaka-shi (JP)

(21) Appl. No.: 13/547,907

(22) Filed: Jul. 12, 2012

(30) Foreign Application Priority Data
Jul. 19, 2011 (JP) 2011-157849

(51) Int. Cl. H01L 29/20

(52) U.S. Cl. 257/76; 257/E29.089

(57) ABSTRACT

An epitaxial wafer including nitride-based semiconductor layers usable for a hetero-junction field effect type transistor, includes a first buffer layer of AlN or AlON, a second buffer layer of AlₓGa₁₋ₓN having its Al composition ratios decreased in a stepwise fashion, a third buffer layer including a multilayer of repeatedly stacked AlₐGa₁₋ₐN layers/Al_{b}Ga_{1-b}N layers disposed on the second buffer layer, a GaN channel layer, and an electron supply layer in this order on a Si substrate, wherein the Al composition ratio x in the uppermost part of the second buffer layer is in a range of 0≦x≦0.3.

This nonprovisional application is based on Japanese Patent Application No. 2011-157849 filed on Jul. 19, 2011 with the Japan Patent Office, the entire contents of which are hereby incorporated by reference.

### BACKGROUND OF THE INVENTION

1. Field of the Invention

The present invention is related to an epitaxial wafer including a plurality of layers of nitride-based semiconductors belonging to III-V group compound semiconductors and particularly to improvement in warpage and crystallinity of the epitaxial wafer usable for a hetero-junction field effect type transistor. Incidentally it is known that two-dimensional electron gas can be generated at a hetero-junction interface in such a nitride-based semiconductor epitaxial wafer.

2. Description of the Background Art

In the case of producing an epitaxial wafer including a hetero-junction interface formed by a GaN channel layer and an AlGaN barrier layer usable for a hetero-junction field effect type transistor for example, the nitride semiconductor layers have conventionally been crystal-grown on a substrate of a different kind of material such as sapphire, Si or the like, because a GaN substrate is expensive.

When a nitride-based semiconductor layer is grown on a Si substrate, one of various buffer layer structures is used in order to relax strains due to the difference of crystal structures, the lattice mismatch, the difference of thermal expansion coefficients, and the like between the substrate and the semiconductor layer. Among such buffer layer structures, buffer layer structures each including two kinds of layers of different compositions stacked repeatedly (hereinafter referred to as multilayered buffer layer structures) are disclosed in many patent documents such as Japanese Patent Laying-Open No. 2010-225703, Japanese Patent Laying-Open No. 2010-245504 and Japanese Patent Laying-Open No. 2010-251738.

Further, as buffer layer structures other than the multilayered buffer layer structures, buffer layer structures each including a buffer layer of which Al composition ratio is changed continuously or in a stepwise fashion (hereinafter referred to as composition-gradient buffer layer structures) are disclosed in Japanese Patent Laying-Open No. 2000-277441, Japanese National Patent Publication No. 2004-524250 and the like.

Regarding the multilayered buffer layer structure, in the case that the repetition number of constituent layers therein is increased and the total thickness from the upper surface of the GaN channel layer thereon to the upper surface of the substrate is increased, there is a problem that the wafer shows a warpage of not a simple parabolic shape but an M-shape as shown in a graph of FIG. 2 and it becomes difficult to control the warpage of the wafer. Here, the horizontal axis in the graph of FIG. 2 represents the radial distance (mm) from the center of the wafer, while the vertical axis represents the warpage amount (μm) in a direction perpendicular to the main surface of the wafer.

In the meantime, as shown in a graph of FIG. 3, when the thickness of the multilayered buffer layer structure is increased, density of edge dislocations included in the GaN channel layer on the buffer layer is decreased. Here, the horizontal axis of the graph represents the total thickness (μm) from the upper surface of the substrate to the upper surface of the GaN channel layer (hereinafter simply referred to as “total thickness”), while the thickness of the GaN channel layer is constant. The vertical axis represents the density (cm⁻²) of edge dislocations included in the GaN channel layer.

As seen in FIG. 3, while the density of edge dislocations included in the GaN channel layer on the multilayered buffer layer structure decreases as the thickness of the buffer layer structure increases, there is a problem that the edge dislocation density is still greater than about 1×10¹⁰ cm⁻² even when the total thickness is about 5 μm.

Incidentally the density of screw dislocations in the GaN channel layer is not influenced by the total thickness including the buffer layer structure and is approximately constant. In the specification of the present application, the edge dislocation density in the GaN channel layer has been evaluated according to a formula (1) as below by using the full width at half maximum (FWHM) of the locking curve of (1-100) plane diffraction in X-ray diffraction measurement. The FWHM in X-ray diffraction due to the (1-100) plane is mainly influenced by the edge dislocation density but is hardly influenced by the screw dislocation density.

Edge dislocation density=(FWHM²/9.0)/3.189 Å (1)

Here the FWHM and the edge dislocation density are related by observation using cathode luminescence (CL). The value “9.0” in formula (1) is a fitting parameter for making the connection between the FWHM and the edge dislocation density based on the CL observation, and 3.189 Å is the length of the Burger's vector of the edge dislocation in the GaN crystal.

In the case of the composition-gradient buffer layer structure, when the total thickness is increased, it is possible to achieve the edge dislocation density less than that in the case of the multilayered buffer layer structure. As shown in a graph of FIG. 4 similar to FIG. 3, however, the edge dislocation density is still as great as approximately 10⁹-10¹⁰ cm⁻² even when the total thickness is about 4 μm.

Regarding the composition-gradient buffer layer structure, there is a possibility that the edge dislocation density is further reduced as the total thickness is increased, as expected from FIG. 4. However, there is a problem that the warpage of the wafer is increased and cracks are generated when the thickness of the composition-gradient buffer layer structure is increased.

Further, even with structures in which the multilayered buffer structure and the composition-gradient buffer structure are combined, there is a problem that in some cases the effect of improving the crystallinity is not realized at all depending on how the multilayered buffer layer structure and the composition-gradient buffer layer structure are combined.

### SUMMARY OF THE INVENTION

In view of the problems as described above, a main object of the present invention is to improve the warpage and crystallinity of the epitaxial wafer usable for the hetero-junction field effect type transistor.

As a result of efforts in investigation, the present inventors have found a novel buffer layer structure with which the edge dislocation density can significantly be reduced at approximately the same total thickness as compared with the conventional multilayered buffer layer structure or composition-gradient buffer layer structure.

According to the present invention, an epitaxial wafer including nitride-based semiconductor layers usable for a hetero-junction field effect type transistor, includes a first buffer layer of AlN or AlON, a second buffer layer of AlₓGa₁₋ₓN having its Al composition ratios decreased in a stepwise fashion, a third buffer layer including a multilayer of repeatedly stacked AlₐGa₁₋ₐN layers/Al_{b}Ga_{1-b}N layers disposed on the second buffer layer, a GaN channel layer, and an electron supply layer in this order on a Si substrate, wherein the Al composition ratio x in the uppermost part of the second buffer layer is in a range of 0≦x≦0.3.

By using the buffer layer structure found in the present invention, it is possible to obtain a nitride-based semiconductor epitaxial wafer having an edge dislocation density significantly reduced as compared with that in the case of using the conventional multilayered buffer layer structure or composition-gradient buffer layer structure.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view illustrating a structure of a nitride-based semiconductor epitaxial wafer according to Example 1 of the present invention.

FIG. 2 is a graph showing a warpage of an M-shape in the case that a nitride-based semiconductor epitaxial wafer includes a multilayered buffer layer structure and has a large total thickness.

FIG. 3 is a graph showing the relation between the total thickness from the upper surface of the substrate to the upper surface of the GaN channel layer on the multilayered buffer layer structure and the density of edge dislocations included in the GaN channel layer.

FIG. 4 is a graph showing the relation between the total thickness from the upper surface of the substrate to the upper surface of the GaN channel layer on the composition-gradient buffer layer structure and the density of edge dislocations included in the GaN channel layer.

FIG. 5 is a SEM (scanning electron microscope) image of surface defects formed on the AlGaN layer in a composition-gradient buffer layer structure.

### DESCRIPTION OF THE PREFERRED EMBODIMENTS

As described above, according to the present invention, an epitaxial wafer including nitride-based semiconductor layers usable for a hetero-junction field effect type transistor, includes a first buffer layer of AlN or AlON, a second buffer layer of AlₓGa₁₋ₓN having its Al composition ratios decreased in a stepwise fashion, a third buffer layer including a multilayer of repeatedly stacked AlₐGa₁₋ₐN layers/Al_{b}Ga_{1-b}N layers disposed on the second buffer layer, a GaN channel layer, and an electron supply layer in this order on a Si substrate, wherein the Al composition ratio x in the uppermost part of the second buffer layer is in a range of 0≦x≦0.3.

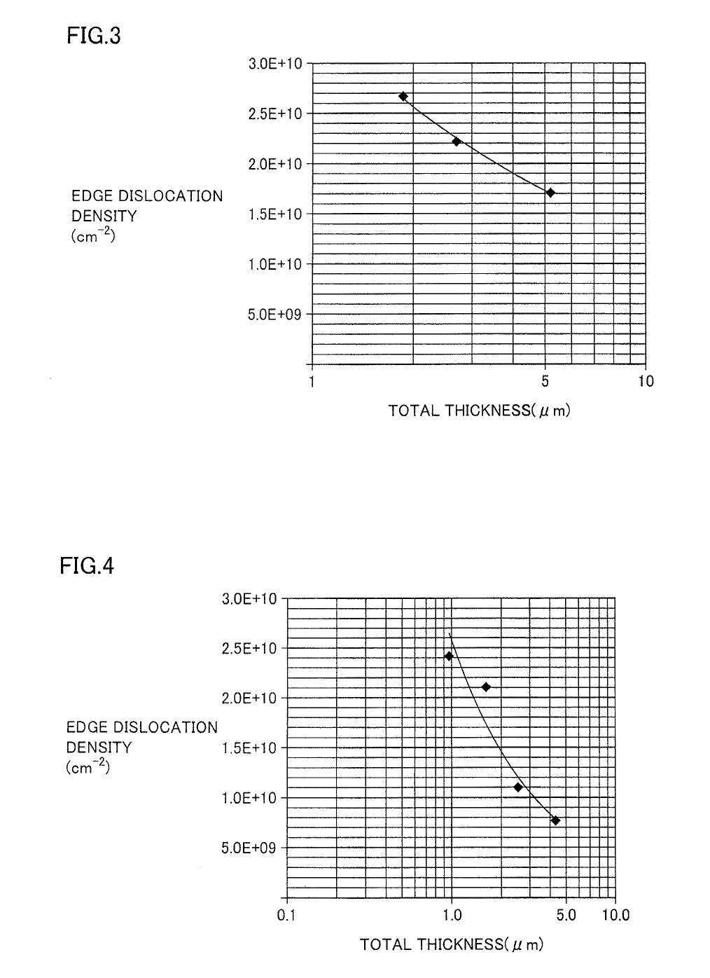

As mentioned above, the graph of FIG. 3 shows the relation between the total thickness from the upper surface of the substrate to the upper surface of the GaN channel layer on the multilayered buffer layer structure and the density of edge dislocations included in the GaN channel layer. From this graph, it is possible to estimate in the case of the multilayered buffer layer structure that the edge dislocation density is about 1.82×10¹⁰ cm⁻² when the total thickness is about 4.4 μm.

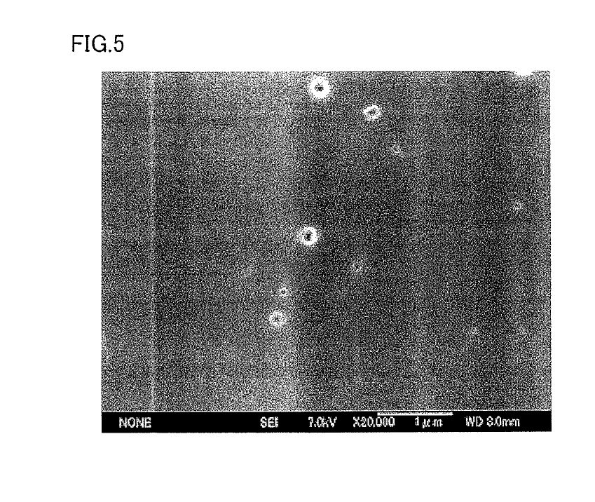

Further, as mentioned above, the graph of FIG. 4 shows the relation between the total thickness from the upper surface of the substrate to the upper surface of the GaN channel layer on the composition-gradient buffer layer structure and the density of edge dislocations included in the GaN channel layer. From this graph, it is possible to estimate in the case of the composition-gradient buffer layer structure that the edge dislocation density is about 7.74×10⁹ cm⁻² when the total thickness is about 4.4 μm.

On the other hand, by combining the multilayered buffer layer structure on the composition-gradient buffer layer structure (hereinafter referred to as combined buffer layer structure) as in the present invention, the edge dislocation density in the GaN channel layer can be reduced to 2.27×10⁹ cm⁻² when the Al composition ratio x in the uppermost part of the composition-gradient buffer layer structure is 0.1, as shown later in Table 1.

Incidentally, in consideration here, the comparisons are made under the total thickness fixed to 4.4 μm from the upper surface of the substrate to the upper surface of the GaN channel layer in order to avoid influence caused by differences in the thicknesses of the buffer layer structures.

The improvement effect as above bringing about the significant decrease of the edge dislocation density is an effect non-predictable from the teaching of each of the multilayered buffer layer structure and the composition-gradient buffer layer structure that have the main object to suppress the warpage of the wafer.

Further, Table 1 also shows a result in the case that the Al composition ratio x in the uppermost part of the composition-gradient buffer layer structure is 0.4. The effect is significantly different between the case of the Al composition ratio x of 0.1 in the uppermost part of the composition-gradient buffer layer structure and the case of the Al composition ratio x of 0.4. This difference has first been revealed by the present invention.

In the multilayered buffer layer structure included in the epitaxial wafer of the present invention, it is preferable that the thickness of the AlₐGa₁₋ₐN layer is equal to or less than ½ of that of the Al_{b}Ga_{1-b}N layer and the relation of the Al composition ratios is a≧b+0.7.

The interrelations between the Al composition ratios and between the thicknesses in the two kinds of the AlGaN layers are also important in order to obtain the sufficient improvement in reduction of the edge dislocation density. The reason for this is that there is a case that the edge dislocation density is rather increased when the combinations of the Al composition ratios and the thicknesses of the two kinds of AlGaN layers are not appropriate.

Therefore, in view of the relation with the GaN channel layer deposited on the buffer layer structure, the thickness of the AlₐGa₁₋ₐN layer having the greater Al concentration is preferably equal to or less than ½ of that of the Al_{b}Ga_{1-b}N layer having the less Al concentration. In the meantime, from the viewpoint of enhancing the strain relaxation effect of the multilayered buffer layer structure, it is preferable that the difference of the Al composition ratios is greater and the condition of a≧b+0.7 is satisfied.

In the GaN channel layer included in the epitaxial wafer of the present invention, the carbon concentration is preferably 5×10¹⁶ cm⁻³ or less. In other words it is preferable that the epitaxial wafer usable for the hetero-junction field effect type transistor has its characteristic contributable to prevention of the current collapse of the transistor. For that characteristic, the carbon concentration of the GaN channel layer included in the wafer is preferably 5×10¹⁶ cm⁻³ or less.

In the meantime the GaN channel layer preferably includes two layers of a carbon-doped GaN layer having a carbon concentration of 1×10¹⁸ cm⁻³ or more and an undoped GaN layer having a carbon concentration of 5×10¹⁶ cm⁻³ or less.

It is also desirable that the epitaxial wafer for the hetero-junction type transistor has as its property a good withstand voltage in the thickness direction. As a measure of improving the withstand voltage in the thickness direction, it is possible to dope the lower layer part of the GaN channel layer with carbon to a concentration of 1×10¹⁸ cm⁻³ or more so as to improve the withstand voltage in the thickness direction and provide an undoped GaN layer having a carbon concentration of 5×10¹⁶ cm⁻³ or less as the upper layer part of the GaN channel layer so as to contribute to prevention of the current collapse.

The electron supply layer included in the epitaxial wafer of the present invention preferably includes an AlN characteristic improvement layer containing four or less pairs of Al atomic layers and N atomic layers, an AlGaN barrier layer and a GaN cap layer in this order.

For characteristic improvement of the hetero-junction structure, it is desirable to suppress the alloy scattering of carriers at the interface between the GaN channel layer and the AlGaN barrier layer. In connection with this, by inserting an AlN characteristic improvement layer at the interface between the GaN channel layer and the AlGaN barrier layer, it is possible to suppress the alloy scattering and then improve the mobility of two-dimensional electron gas. However if the pairs of the Al atomic layers and the N atomic layers are increased to more than four pairs, the improvement effect of the carrier mobility is reduced due to deterioration of the crystallinity.

### Example 1

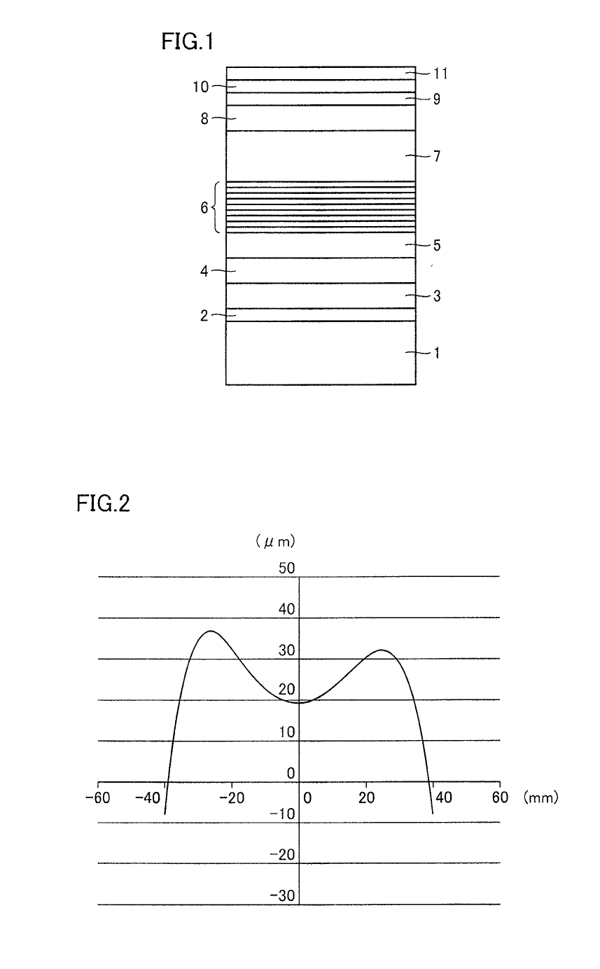

FIG. 1 is a schematic cross-sectional view illustrating an epitaxial wafer for a hetero-junction field effect type transistor, according to Example 1 of the present invention.

In production of this wafer, a Si substrate 1 of a 4-inch diameter is used as a substrate. Prior to crystal growth of nitride-based semiconductor layers, the surface oxide film of Si substrate 1 is removed by hydrofluoric acid type etchant and then the substrate is set in a chamber of a MOCVD (metal organic chemical vapor deposition) apparatus.

In the MOCVD apparatus, the substrate is heated to 1100° C. and the substrate surface is cleaned in a hydrogen atmosphere at a chamber pressure of 13.3 kPa.

Then while the substrate temperature and the chamber pressure are maintained, the Si substrate surface is nitrided by letting ammonia NH₃ (12.5 slm) flow. Subsequently an AlN layer 2 is deposited to a thickness of 200 nm under the conditions of a TMA (trimethylaluminum) flow rate of 117 μmol/min and a NH₃ flow rate of 12.5 slm.

Thereafter the substrate temperature is raised to 1150° C. and an Al_{0.7}Ga_{0.3}N layer 3 is deposited to a thickness of 400 nm under the conditions of a TMG (trimethylgallium) flow rate of 57 μmol/min, a TMA flow rate of 97 μmol/min and NH₃ flow rate of 12.5 slm. Subsequently an Al_{0.4}Ga_{0.6}N layer 4 is deposited to a thickness of 400 nm under the conditions of a TMG flow rate of 99 μmol/min, a TMA flow rate of 55 μmol/min and NH₃ flow rate of 12.5 slm and further an Al_{0.1}Ga_{0.9}N layer 5 is deposited to a thickness of 400 nm under the conditions of a TMG flow rate of 137 mmol/min, a TMA flow rate of 18 μmol/min and NH₃ flow rate of 12.5 slm. Accordingly a composition-gradient buffer layer structure 3-5 is formed.

At the same substrate temperature, a multilayered buffer layer structure 6 including AlN layers (5 nm thick each)/Al_{0.1}Ga_{0.9}N layers (20 nm thick each) repeated with 50 cycles is deposited on Al_{0.1}Ga_{0.9}N layer 5. At this time the AlN layer is deposited under the conditions of a TMA flow rate of 102 μmol/min and NH₃ flow rate of 12.5 slm and the Al_{0.1}Ga_{0.9}N layer is deposited under the conditions of a TMG flow rate of 720 μmol/min, a TMA flow rate of 80 μmol/min and NH₃ flow rate of 12.5 slm.

Thereafter the substrate temperature is lowered to 1100° C. and a GaN layer 7 is deposited under a pressure of 13.3 kPa to a thickness of 1.0 μm under the conditions of a TMG flow rate of 224 mmol/min and NH₃ flow rate of 12.5 slm and then a GaN layer 8 is deposited under a pressure of 90 kPa to a thickness of 0.5 μm. Here, the GaN layer tends to be doped more with carbon contained in TMG when the deposition pressure is lower, while the GaN layer tends to be doped less with carbon from TMG when the deposition pressure is higher.

Further an electron supply layer including an AlN characteristic improvement layer 9 (1 nm thick), an Al_{0.1}Ga_{0.8}N barrier layer 10 (20 nm thick) and a GaN cap layer 11 (1 nm thick) is deposited under a pressure of 13.3 kPa on GaN layer 8. At this time AlN layer 9 is deposited under the conditions of a TMA flow rate of 51 μmol/min and NH₃ flow rate of 12.5 slm, AlGaN layer 10 is deposited under the conditions of a TMG flow rate of 46 μmol/min, a TMA flow rate of 7 μmol/min and NH₃ flow rate of 12.5 slm, and GaN layer 11 is deposited under the conditions of TMG flow rate of 58 μmol/min and NH₃ flow rate of 12.5 slm.

TABLE 1

| | FWHM of (1-100) Plane | Edge Dislocation |
|---|---|---|
| Buffer Structure | Diffraction (arcsec) | Density (cm⁻²) |
| Combined Buffer | 940 | 2.27 × 10⁹ |
| x = 0.1 | | |
| Combined Buffer | 1832 | 8.62 × 10⁹ |
| x = 0.4 | | |
| Multilayered Buffer | 2662 | 1.82 × 10¹⁰ |
| Composition-gradient | 1736 | 7.74 × 10⁹ |
| Buffer | | |

Table 1 shows the FWHM of the (1-100) plane diffraction and the edge dislocation density obtained by the X-ray measurement of the epitaxial wafers formed by the method as described above. In the left column of this Table, the “Combined Buffer” represents that the epitaxial wafer includes a combined buffer layer structure according to Example 1 as described above, the “Multilayered Buffer” represents that the wafer is different from that of Example 1 only in that it includes as its buffer structure only a multilayered buffer layer structure, and the “Composition-gradient Buffer” represents that the buffer is different from that of Example 1 only in that it includes only a composition-gradient buffer structure. The central column of Table 1 shows the FWHM (arcsec) of the (1-100) reflection in the X-ray diffraction. The right column of Table 1 shows the edge dislocation density (cm-2). As shown in Table 1, it is seen that the wafer including the combined buffer layer structure according to Example 1 has a dislocation density of 2.27×109 cm-2 significantly reduced as compared with the edge dislocation density of 1.82×1010 cm-2 in the wafer including only the multilayered buffer layer structure and the edge dislocation density of 7.74×109 cm-2 in the wafer including only the composition-gradient buffer layer structure.

Incidentally while the Al composition ratios of AlGaN layers 3, 4 and 5 are varied to 0.7, 0.4 and 0.1 respectively, the combination of the Al composition ratios in the AlGaN layers included in the composition-gradient buffer layer structure are not limited to this combination. Further, the number of the AlGaN layers having the different Al composition ratios and included in the composition-gradient buffer layer structure is not restricted to three layers and can have an arbitrary number of layers. What is critical is that the Al composition ratio is gradually decreased from the lower surface to the upper surface of the composition-gradient buffer layer structure.

While Example 1 has described the case that MN layer 2 is deposited as a first buffer layer on Si substrate 1 by MOCVD, it is preferable to deposit an AlON layer in the case that the first buffer layer is deposited by sputtering.

Further, while multilayered buffer layer structure 6 is inserted between Al0.1Ga0.9N layer 5 and GaN layer 7, it is necessary that the Al composition ratio x of the layer under multilayered buffer layer structure 6 is in a range of 0≦x≦0.3. When the Al composition ratio x is made larger than 0.3, surface defects (pits) as shown in a SEM (scanning electron microscope) photograph of FIG. 5 are formed on the surface of the underlayer beneath the multilayered buffer layer structure. In this case, a sufficient improvement effect in reduction of the edge dislocation density cannot be obtained as shown in Table 1. Incidentally a scale of a white line segment at the bottom of the SEM photograph of FIG. 5 represents a length of 1 μm. In general, these surface defects on the AlGaN layer tend to be generated when the Al composition ratio is higher. While the generation of the surface defects tends to be suppressed by surface diffusion when the substrate temperature is higher and the deposition rate is lower, it is desirable that the Al composition ratio x is made 0.3 or less in order to completely prevent the generation.

In the meantime, regarding the interrelation in the Al composition ratios and the thicknesses of the constituent layers included in the multilayered buffer layer structure, the combination is not restricted to the MN layer (5 nm thick) and Al0.1Ga0.9N layer (20 nm thick), and the effect can be obtained with any other combination as long as the relation of the Al composition ratios is a≧b+0.7 and the thickness of the AlaGa1-aN layer is equal to or less than ½ of that of the AlbGa1-bN layer.

Further, the Al composition ratio of the AlGaN barrier layer is not restricted to the value shown in Example 1, and it can be varied so as to obtain a desired sheet carrier density.

As described above, according to the present invention, it is possible to significantly reduce the edge dislocation density in the epitaxial wafer including the nitride-based semiconductor layers for the hetero-junction field effect type transistor and then provide the hetero-junction field effect type transistor in which the current collapse hardly occurs.

Although the present invention has been described and illustrated in detail, it is clearly understood that the same is by way of illustration and example only and is not to be taken by way of limitation, the scope of the present invention being interpreted by the terms of the appended claims.

What is claimed is:

1. An epitaxial wafer including nitride-based semiconductor layers usable for a hetero-junction field effect type transistor, comprising:
a first buffer layer of AlN or AlON;
a second buffer layer of AlₓGa₁₋ₓN having its Al composition ratios decreased in a stepwise fashion;
a third buffer layer including a multilayer of repeatedly stacked AlₐGa₁₋ₐN layers/Al_{b}Ga_{1-b}N layers disposed on the second buffer layer;
a GaN channel layer; and
an electron supply layer in this order on a Si substrate;
wherein the Al composition ratio x in the uppermost part of the second buffer layer is in a range of 0≦x≦0.3.

2. The epitaxial wafer according to claim 1, wherein in said third buffer layer, the Al composition ratios have a relation of a≧b+0.7, and thickness of each AlₐGa₁₋ₐN layer is equal to or less than ½ of that of each Al_{b}Ga_{1-b}N layer.

3. The epitaxial wafer according to claim 1, wherein said GaN channel layer contains carbon at a concentration of 5×10¹⁶ cm⁻³ or less.

4. The epitaxial wafer according to claim 1, wherein said GaN channel layer includes a first channel layer doped with carbon at a concentration of 1×10¹⁸ cm⁻³ or more and a second channel layer thereon undoped and having a carbon concentration of 5×10¹⁶ cm⁻³ or less.

5. The epitaxial wafer according to claim 1, wherein said electron supply layer comprises AlN characteristic improvement layer including four or less pairs of Al atomic layers and N atomic layers; an AlGaN barrier layer; and GaN cap layer in this order.
